(19) United States
(12) Patent Application Publication
(10) Pub. No.: US 2012/0243191 A1
(43) Pub. Date: Sep. 27, 2012

(54) MINIATURIZED ELECTROMAGNETIC INTERFERENCE SHIELDING STRUCTURE AND MANUFACTURING METHOD THEREOF

(75) Inventor: MING-CHE WU, NANTOU COUNTY (TW)

(73) Assignees: UNIVERSAL GLOBAL SCIENTIFIC INDUSTRIAL CO., LTD., NANTOU COUNTY (TW); UNIVERSAL SCIENTIFIC INDUSTRIAL (SHANGHAI) CO., LTD., SHANGHAI (CN)

(21) Appl. No.: 13/207,531

(22) Filed: Aug. 11, 2011

(30) Foreign Application Priority Data
Mar. 23, 2011 (TW) 100109932

(51) Int. Cl. H05K 1/18; H05K 3/00; H05K 9/00

(52) U.S. Cl. 361/760; 361/818; 29/829

(57) ABSTRACT

A miniaturized electromagnetic interference (EMI) shielding structure is disclosed, which includes a substrate and a plurality of chip modules disposed thereon. The substrate has a plurality of ground portions formed thereon. Each chip module includes: at least one chip unit disposed on the substrate and connected electrically thereto; at least one conductive bump disposed on the substrate adjacent to the chip unit and connected electrically to the corresponding ground portion; an encapsulation layer arranged on the substrate and covers the chip unit and the conductive bump; and an EMI shielding layer covering the encapsulation layer and electrically connected with an exposed surface of the conductive bump, to allow the EMI shielding layer be electrically connected to the ground portion. The disclosure of the present invention allows each chip module to have its own EMI shielding capability.

### BACKGROUND OF THE INVENTION

1. Field of the Invention

The present invention relates to an electromagnetic interference (EMI) shielding structure; in particular, to a miniaturized EMI shielding structure and a manufacturing method thereof.

2. Description of Related Art

Electronic components are indispensable elements among all kinds of technological products, such as various electric appliances, 3C products, and other products which need to be controlled by electric circuits. Among the electronic components of the mentioned products, there may have at least one kind of electromagnetic interference (EMI) shielding structures. The main functionalities of the EMI shielding structures are for preventing the electronic components from influencing the outer environments, or avoiding the units or modules within the electronic components from interfering one another. The EMI shielding structure mainly includes the substrate unit, the electronic circuit unit, the metal shielding unit, and the electrical connection unit. The electronic components can work normally in a non-interfering environment by the shielding effect provided by the EMI shielding structures.

Presently, there are still rooms for improving the techniques of making the EMI shielding structures. For example, the entire structure is too complicated, product thickness is too thick, the shielding effect is poor, and the surfaces of the structure are too easy to become rusty. Therefore, the improvements, researches, and designs for producing a simple, light, thin, excellent shielding capability, and anti-rusting EMI shielding structure are the primary works to be done.

### SUMMARY OF THE INVENTION

The object of the present invention is to disclose a miniaturized electromagnetic interference (EMI) shielding structure and manufacturing method thereof which have the functionality of EMI shielding.

In order to achieve the aforementioned objects, according to an embodiment of the present invention, a miniaturized EMI shielding structure is disclosed. The miniaturized EMI shielding structure includes a substrate and a plurality of chip modules. The surface of the substrate has a plurality of ground portions. The chip modules are arranged on the top surface of the substrate, wherein each chip module includes at least one chip unit, at least one conductive bump, an encapsulation layer, and an EMI shielding layer. The chip unit is set on the top surface of the substrate and is electrically connected thereto. The conductive bump is set on the top surface of the substrate and near the chip unit, and is further electrically connected to the ground portion of the substrate. The encapsulation layer is set on the substrate, and covers the surface of the chip unit and the surface of the conductive bump. The EMI shielding layer covers the surface of the encapsulation layer and is electrically connected with the conductive bump, for making an electrical connection between the EMI shielding layer and the ground portion.

In addition, a manufacturing method of a miniaturized EMI shielding structure is disclosed according to an embodiment of the present invention. The method includes a step of disposing a plurality of chip units on the top surface of a substrate which has a plurality of ground portions formed thereon. The method also includes a step of forming a plurality of conductive bumps which are arranged on the top surface of the substrate and are electrically connected with respective ground portions, wherein the conductive bumps are arranged near the chip units. The method further has a step of forming an encapsulation layer on the substrate, for covering the chip units and the conductive bumps. The method further includes a step of cutting the encapsulation unit and every conductive bump, for dividing the encapsulation unit into a plurality of encapsulation layers covering respective chip units, and for exposing a surface of every conductive bump from a side portion of the encapsulation layer, a step of covering the surface of every encapsulation layer and the exposed surface of every conductive bump simultaneously with an EMI shielding unit. Moreover, the method further includes a step of cutting the EMI shielding unit along a space between two adjacent encapsulation layers, for dividing the EMI shielding unit into a plurality of EMI shielding layers which cover the respective encapsulation layers. Therefore, the miniaturized EMI shielding structure can be produced according to the aforementioned steps.

On the basis of the above, the miniaturized EMI shielding structure according to the embodiments of the present invention provides a miniaturized solution of EMI shielding. By cutting out part of the encapsulation unit, conductive bump, and EMI shielding unit, the size of every chip module can be miniaturized, and every chip module can have its own EMI shielding capability.

For further understanding of the present disclosure, reference is made to the following detailed description illustrating the embodiments and examples of the present disclosure. The description is only for illustrating the present disclosure, not for limiting the scope of the claim.

### BRIEF DESCRIPTION OF THE DRAWINGS

The drawings included herein provide further understanding of the present disclosure. A brief introduction of the drawings is as follows:

FIG. 1 shows a cross-sectional view of a first step in forming a miniaturized electromagnetic interference (EMI) shielding structure according to a first embodiment of the present invention;

FIG. 2 shows a cross-sectional view of a second step in forming the miniaturized EMI shielding structure according to the first embodiment of the present invention;

FIG. 3 shows a cross-sectional view of a third step in forming the miniaturized EMI shielding structure according to the first embodiment of the present invention;

FIG. 4 shows a cross-sectional view of a fourth step in forming the miniaturized EMI shielding structure according to the first embodiment of the present invention;

FIG. 5 shows a cross-sectional view of a fifth step in forming the miniaturized EMI shielding structure according to the first embodiment of the present invention;

FIG. 6 shows a cross-sectional view of a sixth step in forming the miniaturized EMI shielding structure according to the first embodiment of the present invention;

FIG. 7 shows a partial view of an EMI shielding layer according to the first embodiment of the present invention;

FIG. 8 shows a flow diagram of a manufacturing method of the miniaturized EMI shielding structure according to the first embodiment of the present invention;

FIG. 9 shows a cross-sectional view of a fifth step in forming a miniaturized EMI shielding structure according to a second embodiment of the present invention;

FIG. 10 shows a cross-sectional view of a sixth step in forming the miniaturized EMI shielding structure according to the second embodiment of the present invention; and

FIG. 11 shows a cross-sectional view of a seventh step in forming the miniaturized EMI shielding structure according to the second embodiment of the present invention.

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended drawings.

### First Embodiment

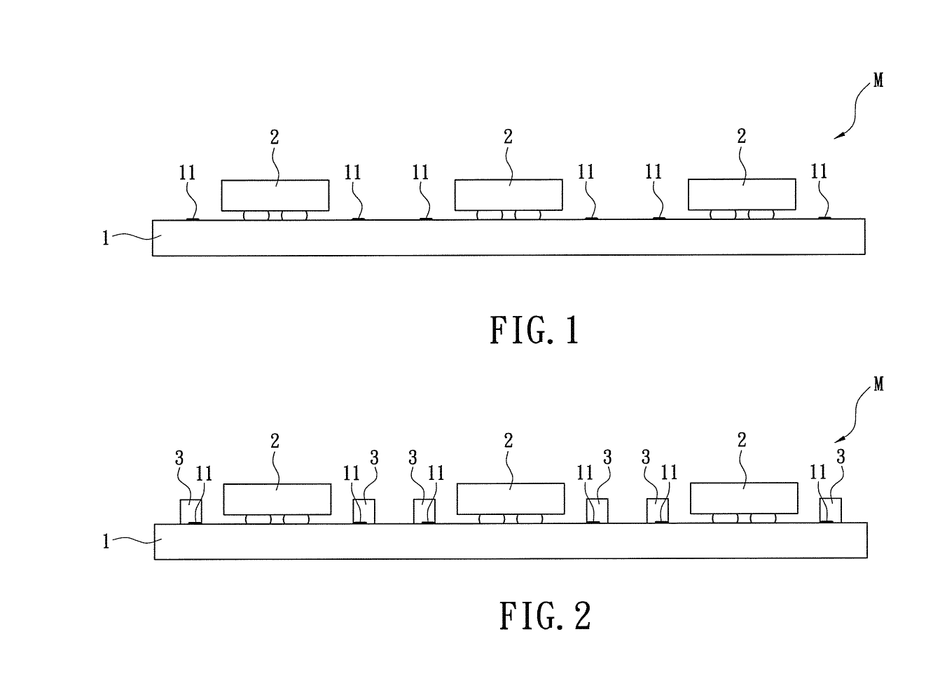

Please refer to FIG. 1 to FIG. 6, which are the cross-sectional views of the first step, second step, third step, fourth step, fifth step, and sixth step in forming a first embodiment of the present invention, respectively. The manufacturing method of a miniaturized electromagnetic interference (EMI) shielding structure M of the instant disclosure includes the steps as follows.

First Step (Please Refer to FIG. 1).

Firstly, disposing a plurality of chip units 2 on the top surface of a substrate 1 which has a plurality of ground portions 11 formed thereon.

Second Step (Please Refer to FIG. 2).

Forming a plurality of conductive bumps 3, which are arranged on the top surface of the substrate 1 and are electrically connected with the respective ground portions 11. These conductive bumps 3 are arranged adjacent to the chip units 2. The conductive bumps 3 may be formed of metals, such as any conductive metal materials.

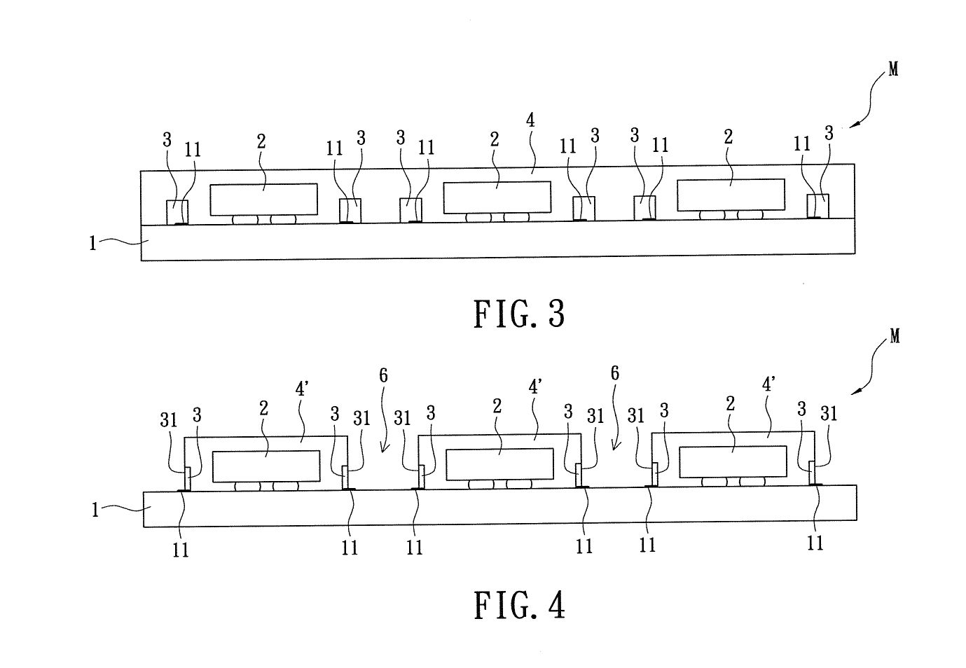

Third Step (Please Refer to FIG. 3).

Forming an encapsulation unit 4 on the substrate 1, for covering the chip units 2 and the conductive bumps 3. That is, the encapsulation unit 4 covers all of the components on the substrate 1.

Fourth Step (Please Refer to FIG. 4).

Cutting the encapsulation unit 4 and every conductive bump 3, for dividing the encapsulation unit 4 into a plurality of encapsulation layers 4′ which cover the respective chip units 2. By removing part of the encapsulation unit 4 and the conductive bumps 3, the encapsulation unit 4 is divided into a plurality of encapsulation layers 4′, while each conductive bump 3 has an exposed surface 31 through the side portion of the encapsulation layer 4′.

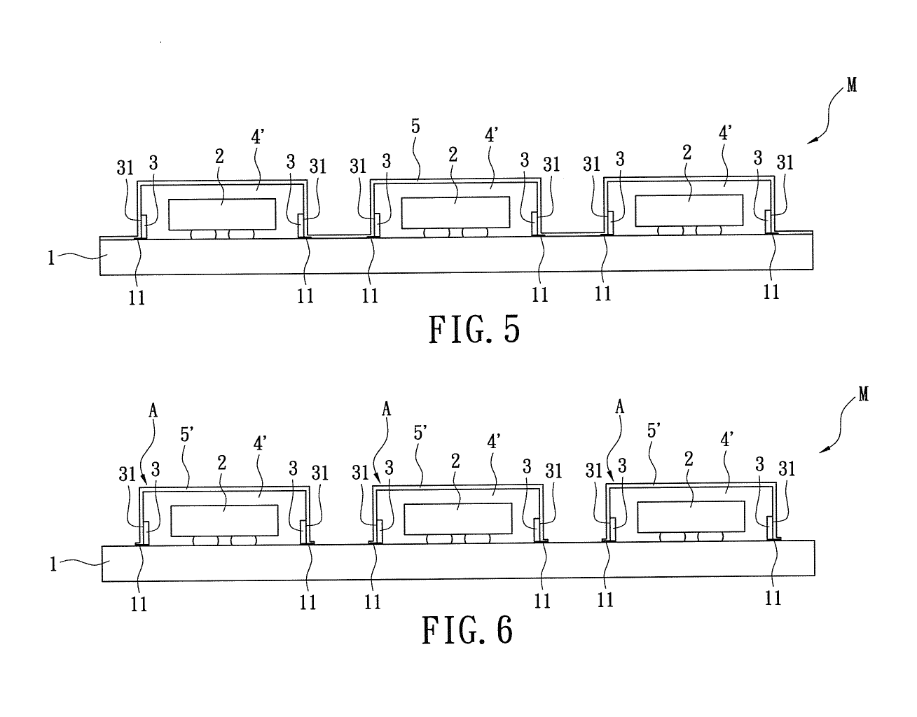

Fifth Step (Please Refer to FIG. 5).

Covering the surface of every encapsulation layer 4′ and the exposed surface 31 of every conductive bump 3 and the space between two of the encapsulation layers 4′ simultaneously with an EMI shielding unit 5. That is, the EMI shielding unit 5 covers the surfaces of all the components on the substrate 1, and is electrically connected with the conductive bumps 3.

Sixth Step (Please Refer to FIG. 6).

Cutting the EMI shielding unit 5 along a space between two of the encapsulation layers 4′, for dividing the EMI shielding unit 5 into a plurality of EMI shielding layers 5′ which cover the respective encapsulation layers 4′. That is, by cutting out part of the EMI shielding unit 5, the EMI shielding unit 5 may be separated into several pieces. Therefore, every chip unit 2 may has its own EMI shielding structure. In this embodiment, the method may be selectively ended at the fifth step or the sixth step, and no matter where the steps end, the miniaturized EMI shielding structures M could be formed.

In the fourth step, the cutting operation is only applied to the encapsulation unit 4 and the conductive bump 3 without cutting through the substrate 1. If the fourth step cuts the substrate 1 into several substrate blocks, the sputtering or electroless plating operations of the next step may not be batched. Because they need to be arranged properly before going into sputtering or electroless plating processes, which would waste time and money.

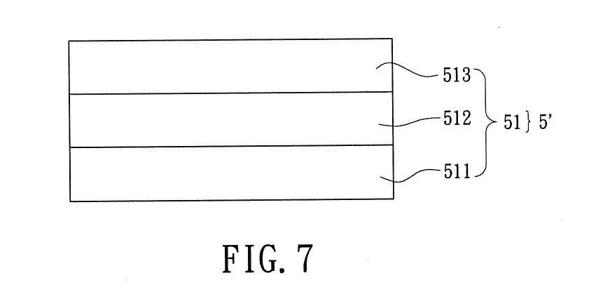

In the fifth step, the EMI shielding unit 5 may have a plurality of metal sputtering layer 51 which is used for preventing the EMI effect between the chip unit 2 and the ambient. The metal sputtering layers 51 of the miniaturized EMI shielding structure M according to the present invention may include a first stainless steel sputtering layer 511 that covers the surfaces of the encapsulation layers 4′ and the exposed surfaces 31 of the conductive bumps 3, a first copper sputtering layer 512 covering the surface of the first stainless sputtering layer 511, and a second stainless sputtering layer 513 covering the surface of the first copper sputtering layer 512 (please refer to FIG. 7, which is a partial view of the EMI shielding layer 5′).

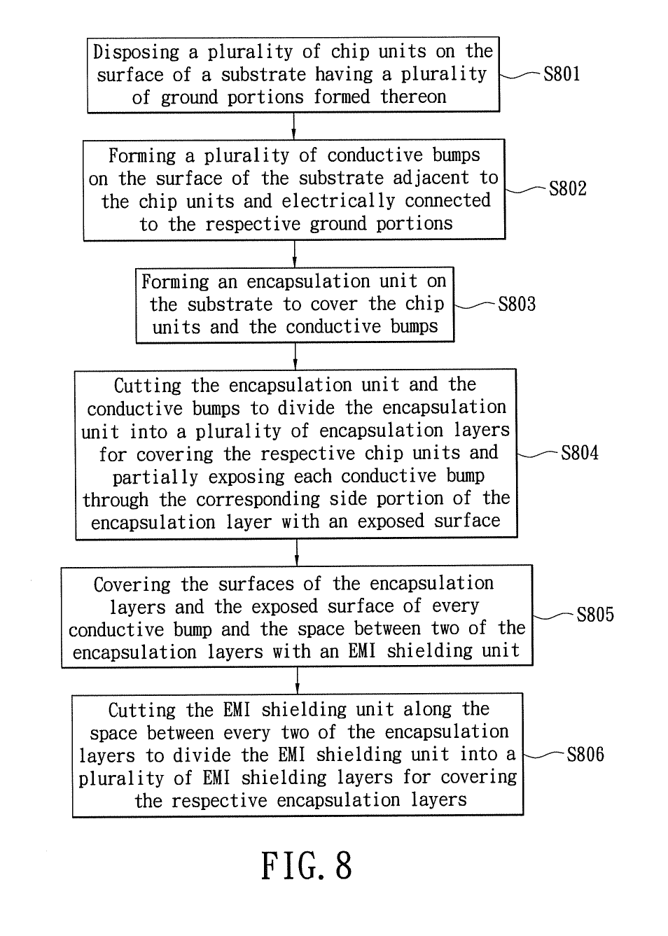

Please refer to FIG. 8 which is a flow chart of a manufacturing method of the miniaturized EMI shielding structure according to the present invention. The symbols 5801 to S806 correspond to the first step to the sixth step, respectively, according to the first embodiment of the present invention. The steps of the manufacturing method can be much more understandable by the disclosure of FIG. 8.

Please refer to FIG. 6 again, which is a cross-sectional view of the miniaturized EMI shielding structure M according to the first embodiment of the present invention. In this embodiment, the EMI shielding structure M includes the substrate 1 and a plurality of chip modules A.

The substrate 1 may be a printed circuit board (PCB) or a silicon wafer substrate, which has a plurality of ground portions 11 formed thereon. The chip modules A are disposed on the top surface of the substrate 1, and each chip module A includes at least one chip unit 2, at least one conductive bump 3, the encapsulation layer 4′, and the EMI shielding layer 5′.

The chip units 2 are disposed on the top surface of the substrate 1 and electrically connected thereto. The conductive bumps 3 are arranged on the top surface of the substrate 1 and near the chip units 2. In this embodiment, the conductive bumps 3 are not arranged at the same side of the chip units 2. It's worth noting that the number of the conductive bumps 3 is not restricted, that is, the number of the conductive bumps 3 could be one or greater than three. The conductive bump 3 is electrically connected to the ground portion 11 of the substrate 1.

The encapsulation layer 4′ is disposed on the substrate 1 and covers the surfaces of the chip unit 2 and the conductive bump 3. In addition, the EMI shielding layer 5′ covers the surface of the encapsulation layer 4′ and the exposed surfaces 31 of the conductive bumps 3. That is, the EMI shielding layer 5′ covers the surfaces of the encapsulation layer 4′ and the exposed surfaces of the conductive bumps 3 from the encapsulation layer 4′, in order to form an electrical connection between the EMI shielding layer 5′ and the ground portions 11 via the conductive bumps 3.

The EMI shielding layer 5′ includes several metal sputtering layers 51 which are formed sequentially and used for preventing the chip units 2 from influencing one another (please refer to FIG. 7, which is a partial view of the EMI shielding layer 5′). Through experiments and practical tests, when the stainless steel sputtering layers and the copper sputtering layers are sequentially plated on the surfaces of a structure, the optimum EMI shielding effect with the anti-oxidizing capability is created. However, the materials of the sputtering layers are not restricted, and may be other metal materials having good electrical conductivity and anti-oxidizing capability. Through continuous researches and tests of the arrangement of the metal sputtering layers 51, the optimum EMI shielding and anti-oxidizing capabilities may be identified. The metal sputtering layers 51 which are made by sputtering processes may also be metal layers formed by electroless plating processes.

### Second Embodiment

Please refer to FIGS. 1 to 4 and FIGS. 9 to 11, which are the cross-sectional views of the first, second, third, fourth, fifth, sixth, and seventh steps of manufacturing the miniaturized EMI shielding structure of a second embodiment of the present invention, respectively. The first through fourth step of the second embodiment are identical to the first embodiment, thus their descriptions and element notations could be the same. According to the second embodiment of a manufacturing method of the miniaturized EMI shielding structure of the present invention, the steps of the method are as follows.

As shown in FIGS. 1 to 4, after the first step to the fourth step is performed, the substrate 1 having a plurality of conductive bumps 3 on its top surface may be obtained. Each conductive bump 3 is partially exposed through the side portion of the encapsulation layer 4′ with the exposed surface 31. A receiving space 6 is formed between every two encapsulation layers 4′. Therefore, there are a number of the receiving spaces 6 formed in this embodiment.

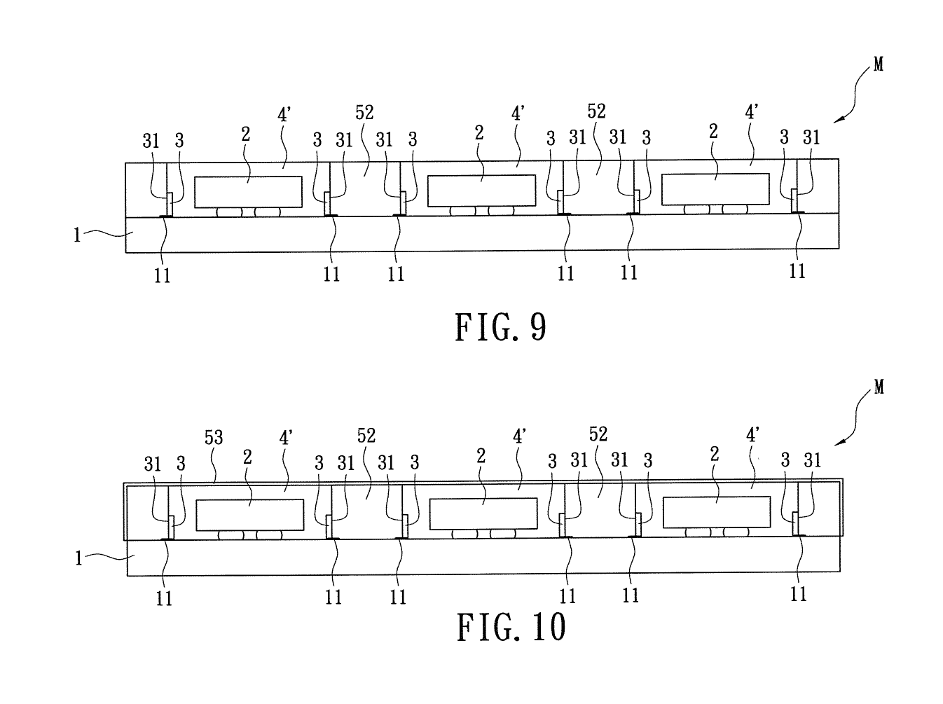

Then, for the fifth step (please refer to FIG. 9), a plurality of conductive layers 52 are filled into the receiving spaces 6. That is, the conductive layers 52 are disposed between every two encapsulation layers 4′. In addition, the conductive layers 52 are in contact with the exposed surfaces 31 of the conductive bumps 3 and the ground portions 11 for electrically connecting to one another. The conductive layers 52 may be formed of silver colloid or any other type of conductive colloid.

Sixth Step (Please Refer to FIG. 10).

Covering the surfaces of every conductive layer 52 and encapsulation layer 4′ by a shielding layer 53. That is, the shielding layer 53 and the conductive layers 52 are electrically connected by being in contact with each other. Therefore, the shielding layer 53 is also electrically connected to the ground portions 11 through the conductive layers 52.

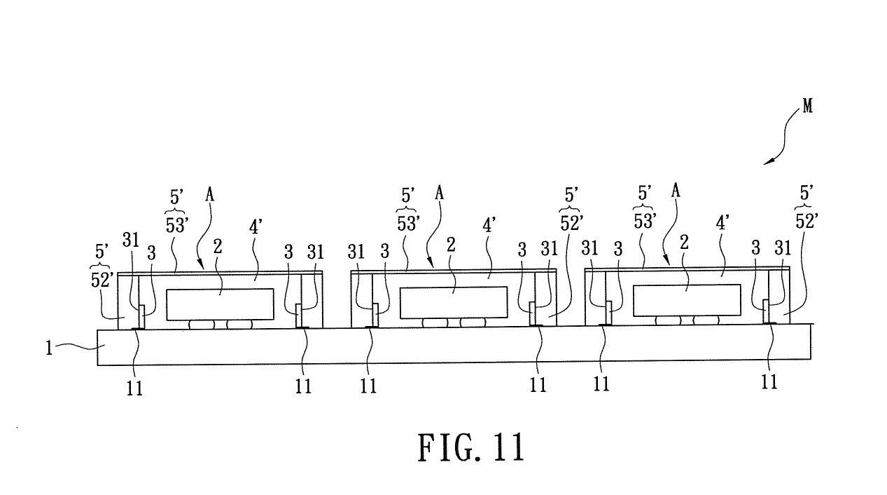

Seventh Step (Please Refer to FIG. 11).

Cutting the shielding layer 53 and every conductive layer 52, with the shielding layer 53 being cut into a plurality of first metal layers 53′, and each conductive layer 52 is cut into at least two second metal layers 52′. The first metal layers 53′ cover the top surfaces of the respective encapsulation layers 4′, and the second metal layers 52′ cover the side surfaces of respective encapsulation layers 4′ and exposed surfaces 31 of the conductive bumps 3. That is, each conductive layer 52 is cut into two independent parts. By cutting out part of the shielding layer 53 and the conductive layers 52, a plurality of EMI shielding layers 5′ are formed. Each EMI shielding layer 5′ includes the first metal layer 53′ and the second metal layer 52′. It's worth noting that the manufacturing method of the second embodiment may selectively end at the sixth step or the seventh step, and no matter what the selection is, the miniaturized EMI shielding structure M of the present invention may be fabricated.

The second embodiment of the present invention covers the side surface of the encapsulation layer 4′ with the second metal layer 52′ and covers the top surface of the encapsulation layer 4′ with the first metal layer 53′, in order to reach the objective of EMI shielding, and prevent the electromagnetic interference between the electrical component and the ambient and/or among different electrical components.

[Possible Efficacy of the Embodiments]

According to the miniaturized EMI shielding structure of the embodiments of the present invention, by cutting out part of the encapsulation unit, conductive bumps, and EMI shielding unit, each chip module can be miniaturized and protected against EMI effect.

Some modifications of these examples, as well as other possibilities will, on reading or having read this description, or having comprehended these examples, will occur to those skilled in the art. Such modifications and variations are comprehended within this disclosure as described here and claimed below. The description above illustrates only a relative few specific embodiments and examples of the present disclosure. The present disclosure, indeed, does include various modifications and variations made to the structures and operations described herein, which still fall within the scope of the present disclosure as defined in the following claims.

What is claimed is:

1. A miniaturized electromagnetic interference shielding structure, comprising:
a substrate having a plurality of ground portions formed thereon; and
a plurality of chip modules disposed on the top surface of the substrate, wherein each of the chip modules includes:
at least one chip unit arranged on the top surface of the substrate and electrically connected thereto;
at least one conductive bump disposed on the top surface of the substrate in close proximity to the chip unit, wherein the conductive bump is electrically connected to the corresponding ground portion on the substrate;
an encapsulation layer disposed on the substrate for covering the chip unit and the conductive bump; and
an electromagnetic interference (EMI) shielding layer covering the encapsulation layer and electrically connected to an exposed surface of the conductive bump for electrically connecting with the ground portions of the substrate.

2. The miniaturized electromagnetic interference shielding structure according to claim 1, wherein the substrate is a printed circuit board (PCB) or a silicon wafer substrate.

3. The miniaturized electromagnetic interference shielding structure according to claim 1, wherein the EMI shielding layer includes a plurality of metal sputtering layers formed sequentially and used for protecting the chip unit against external EMI from the ambient.

4. The miniaturized electromagnetic interference shielding structure according to claim 3, wherein the metal sputtering layers include a first stainless steel sputtering layer which covers the surface of the encapsulation layer and the exposed surface of the conductive bump, a first copper sputtering layer which covers the surface of the first stainless steel sputtering layer, and a second stainless steel sputtering layer which covers the surface of the first copper sputtering layer.

5. The miniaturized electromagnetic interference shielding structure according to claim 3, wherein the EMI shielding layer is a metal layer formed by an electroless plating process.

6. The miniaturized electromagnetic interference shielding structure according to claim 1, wherein the EMI shielding layer includes a first metal layer and a second metal layer, wherein the first metal layer covers the top surface of the encapsulation layer, and the second metal layer covers the side surfaces of the encapsulation layer and the exposed surface of the conductive bump.

7. A manufacturing method of a miniaturized electromagnetic interference shielding structure, comprising the steps of:
disposing a plurality of chip units on the top surface of a substrate having a plurality of ground portions formed thereon;
forming a plurality of conductive bumps on the top surface of the substrate adjacent to the chip units and electrically connected to the respective ground portions;
forming an encapsulation unit on the substrate for covering the chip units and the conductive bumps;
cutting the encapsulation unit and each conductive bump, for dividing the encapsulation unit into a plurality of encapsulation layers to cover respective chip units, and for allowing each conductive bump to be partially exposed through the corresponding side portion of the encapsulation layer with an exposed surface; and
covering the surface of every encapsulation layer and the exposed surface of every conductive bump and the space between two of the encapsulation layers simultaneously with an electromagnetic interference (EMI) shielding unit.

8. The manufacturing method of the miniaturized electromagnetic interference shielding structure according to claim 7, wherein after the step of covering the surface of every encapsulation layer and the exposed surface of every conductive bump and the space between two of the encapsulation layers simultaneously with the EMI shielding unit, further comprising the step of: cutting the EMI shielding unit along the space between every two of the encapsulation layers to divide the EMI shielding unit into a plurality of electromagnetic interference (EMI) shielding layers for covering the respective encapsulation layers.

9. The manufacturing method of the miniaturized electromagnetic interference shielding structure according to claim 8, wherein the EMI shielding layers are electrically connected with the respective conductive bumps and said conductive bumps are made of metal materials.

10. The manufacturing method of the miniaturized electromagnetic interference shielding structure according to claim 8, wherein the EMI shielding layers include a plurality of first metal layers and a plurality of second metal layers, wherein the first metal layers cover top surfaces of the respective encapsulation layers, and the second metal layers cover the side surfaces of the respective encapsulation layers and the exposed surfaces of the conductive bumps at the same time.

11. The manufacturing method of the miniaturized electromagnetic interference shielding structure according to claim 8, wherein the EMI shielding unit is cut by using a laser cutting method.

12. The manufacturing method of the miniaturized electromagnetic interference shielding structure according to claim 8, wherein each EMI shielding layer includes a plurality of metal sputtering layers formed sequentially for protecting the chip unit against EMI effect from the ambient.

13. A manufacturing method of a miniaturized electromagnetic interference shielding structure, comprising the steps of:
disposing a plurality of chip units on the top surface of a substrate having a plurality of ground portions formed thereon;
forming a plurality of conductive bumps on the top surface of the substrate adjacent to the chip units and electrically connected to the respective ground portions;
forming an encapsulation unit on the substrate for covering the chip units and the conductive bumps;
cutting the encapsulation unit and each conductive bump for dividing the encapsulation unit into a plurality of encapsulation layers to cover the respective chip units, wherein a receiving space is formed between every two encapsulation layers, and wherein each conductive bump is partially exposed through the side portion of the corresponding encapsulation layer with an exposed surface;
forming a conductive layer within each receiving space; and
covering each encapsulation layer and each conductive layer with a shielding layer.

14. The manufacturing method of the miniaturized electromagnetic interference shielding structure according to claim 13, wherein after the step of covering each encapsulation layer and each conductive layer with a shielding layer, further comprising the step of: cutting the shielding layer and each conductive layer, wherein the shielding layer is cut into a plurality of first metal layers, and each conductive layer is cut into at least two second metal layers, wherein the first metal layers cover the top surfaces of respective encapsulation layers, and the second metal layers cover the side surfaces of the respective encapsulation layers and the exposed surfaces of the respective conductive bumps.

15. The manufacturing method of the miniaturized electromagnetic interference shielding structure according to claim 13, wherein the conductive layers are silver colloids.
